(19) United States
(12) Patent Application Publication
(10) Pub. No.: US 2020/0335151 A1
(43) Pub. Date: Oct. 22, 2020

(54) LOW-POWER MEMORY

(71) Applicant: QUALCOMM Incorporated, San Diego, CA (US)

(72) Inventors: Chulmin JUNG, San Diego, CA (US); Keejong KIM, Phoenix, AZ (US); Changho JUNG, San Diego, CA (US); Venugopal BOYNAPALLI, San Diego, CA (US)

(21) Appl. No.: 16/849,616

(22) Filed: Apr. 15, 2020

Related U.S. Application Data
(60) Provisional application No. 62/835,160, filed on Apr. 17, 2019.

(51) Int. Cl. G11C 11/4091; G11C 11/4094; G11C 11/4099; G11C 11/4074; G11C 11/408

(52) U.S. Cl. CPC G11C 11/4091; G11C 11/4094; G11C 11/4085; G11C 11/4074; G11C 11/4099

(57) ABSTRACT

A charge-transfer transistor couples between a bit line and a sense node for a sense amplifier. During a read operation, a charge-transfer driver drives a gate voltage of the charge-transfer transistor to control whether the charge-transfer transistor conducts during a charge-transfer period. Prior to the charge-transfer period, a bitcell is coupled to the bit line to drive a bitcell-effected voltage on to the bit line. The charge-transfer driver drives the gate voltage such that the charge-transfer transistor only conducts when the bitcell-effected voltage equals a pre-charge voltage for the bit line.

### CROSS-REFERENCE TO RELATED APPLICATIONS

This application claims priority to and the benefit of U.S. Provisional Patent Application No. 62/835,160 filed Apr. 17, 2019, which is hereby incorporated by reference in its entirety.

### TECHNICAL FIELD

This application relates to memories, and more particularly to a low-power memory.

### BACKGROUND

In a conventional static random access memory (SRAM), a bitcell connects to a pair of bit lines during a read operation. Prior to the read operation, the bit lines are pre-charged to the power supply voltage used for the bitcell. Depending upon the binary content of the bitcell, it will slightly discharge either the true bit line or the complement bit line in the bit line pair from its pre-charged state. For example, suppose that the bitcell is storing a binary one. Due to the binary one value, the complement bit line will then be discharged from its pre-charged state of being charged to the power supply voltage. But the bitcell will maintain the true bit line at its pre-charged state.

The read operation will thus develop a voltage difference across the bit line pair. This bit line voltage difference is not full rail but instead equals a fraction of the power supply voltage. For example, if the power supply voltage is one volt, the voltage difference may be just 100 millivolts or less. To respond to this relatively small voltage difference typically requires relatively a high-power sense amplifier that lowers density.

Accordingly, there is a need in the art for memories in which the sense amplifier has increased density and improved power efficiency.

### SUMMARY

In accordance with a first aspect of the disclosure, a memory is provided that includes: a bit line; a bitcell configured to charge the bit line to a bitcell-effected voltage during a word line assertion period responsive to a stored bit in the bitcell; a sense amplifier; a first sense node for the sense amplifier; a first charge-transfer transistor having a source connected to the bit line and a drain connected to the first sense node; and a charge-transfer driver configured to charge a gate of the first charge-transfer transistor to a gate voltage during a charge-transfer period to cause the first charge-transfer transistor to conduct responsive to the stored bit being equal to a first binary value and to cause the first charge-transfer transistor to remain off responsive to the stored bit being equal to a complement of the first binary value.

In accordance with a second aspect of the disclosure, a method for sensing a bit stored by a bitcell using a charge-transfer transistor is provided that includes the acts of: pre-charging a bit line to equal a pre-charged voltage while a charge-transfer transistor having a source connected to the bit line and a drain connected to a sense node is off to isolate the sense node from the bit line; following the pre-charging of the bit line, coupling the bitcell to the bit line while the charge-transfer transistor is maintained off to charge the bit line to a bitcell-effected voltage that equals the pre-charged voltage responsive to the bit being equal to a first binary value and that is different from the pre-charged voltage by a bit line difference voltage responsive to the bit being equal to a second binary value; charging a gate for the charge-transfer transistor to a gate voltage during a charge-transfer period, wherein a difference between the gate voltage and the bitcell-effected voltage causes the charge-transfer transistor to conduct responsive to the bit equaling the first binary value and wherein the difference between the gate voltage and the bitcell-effected voltage causes the charge-transfer transistor to remain off responsive to the bit equaling the second binary value; and following a termination of the charge-transfer period, sensing the bit responsive to inverting a voltage of the sense node.

In accordance with a third aspect of the disclosure, a memory is provided that includes: a bit line; a bitcell configured to charge the bit line to a bitcell-effected voltage during a read operation responsive to a bit stored by the bitcell; a sense amplifier inverter; a charge-transfer transistor coupled between the bit line and a sense node for the sense amplifier inverter; and a discharge circuit configured to discharge the sense node to ground prior to a charge-transfer period for the charge-transfer transistor.

In accordance with a fourth aspect of the disclosure, a memory is provided that includes: a bit line; a bitcell configured to charge the bit line to a bitcell-effected voltage during a read operation responsive to a bit stored by the bitcell; a sense amplifier inverter; a charge-transfer transistor coupled between the bit line and a sense node for the sense amplifier inverter; and a charge circuit configured to charge the sense node to a power supply voltage prior to a charge-transfer period for the charge-transfer transistor.

These and additional advantages may be better appreciated through the following detailed description.

### BRIEF DESCRIPTION OF THE DRAWINGS

FIG. 1 illustrates a memory with a single-ended PMOS charge-transfer sensing in accordance with an aspect of the disclosure.

FIG. 2 illustrates a waveform for the current conducted by the charge-transfer transistor in the memory of FIG. 1 as a function of the charge-transfer transistor's source-to-gate voltage.

FIG. 3 illustrates a diode-connected transistor for generating a gate voltage for the charge-transfer transistor in the memory of FIG. 1 in accordance with an aspect of the disclosure.

FIG. 4 illustrates a memory having a double-ended charge-transfer sensing in accordance with an aspect of the disclosure.

FIG. 5 illustrates a memory with a single-ended NMOS charge-transfer sensing in accordance with an aspect of the disclosure.

FIG. 6 is a flowchart for a method of sensing the binary content of a bitcell using a charge-transfer technique in accordance with an aspect of the disclosure.

FIG. 7 illustrates some example electronic systems each incorporating a memory in accordance with an aspect of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

To improve density and power efficiency, a charge-transfer transistor is disclosed for a coupling of a sense amplifier's sense node to a bit line during a read operation. A source for the charge-transfer transistor is tied to the bit line whereas its drain is tied to the sense node. The resulting charge-transfer is so efficient that it enables the use of just a single bit line in some implementations. Alternatively, a bit line pair may assist in the charge-transfer. In a column-multiplexed implementation, the charge-transfer transistor may function as a column multiplexer transistor. Although it is conventional for a sense amplifier to couple to a bit line through a column multiplexer transistor, note that a conventional column multiplexer transistor is controlled as a switch such that it is fully on during the read operation while the sense node is coupled to the bit line.

In contrast to such conventional fully-on operation, the gate for the charge-transfer transistor is charged to a gate voltage that causes the charge-transfer transistor to conduct for only one polarity for the stored binary value in the accessed bitcell. Prior to an assertion of a word line voltage during a read operation, the bit line is charged to a pre-charged voltage while the charge-transfer transistor is maintained off. The word line voltage is then asserted to couple the bitcell to the pre-charged bit line while the charge-transfer transistor is still off. The bitcell will then charge the pre-charged bit line to a bitcell-effected voltage that depends upon the binary content for the bitcell.

Should the bitcell be storing a first binary value, the bitcell-effected voltage equals the pre-charged voltage for the bit line. But if the bitcell is storing a second binary value (the complement of the first binary value), the bitcell-effected voltage is different from the pre-charged voltage by a bit line voltage difference (dvbl). With the bitcell-effected voltage developed, the charge-transfer period may begin while the word line voltage is still asserted. A charge-transfer driver charges the gate voltage for the charge-transfer transistor to have a magnitude between ground and a power supply voltage VDD during the charge-transfer period. Since the source voltage for the charge-transfer transistor equals the bitcell-effected voltage, the gate-to-source voltage for the charge-transfer transistor equals a difference between the gate voltage and the bitcell-effected voltage during the charge-transfer period. Should the accessed bitcell be storing a first binary value such that the bitcell-effected voltage equals the bit line pre-charged voltage, the gate-to-source voltage for the charge-transfer transistor satisfies a threshold voltage of the charge-transfer transistor to cause the charge-transfer transistor to conduct charge to change the sense node voltage from a default voltage established prior to the charge-transfer period. But if the accessed bitcell is storing a second binary value (the complement of the first binary value), the gate-to-source voltage is changed by the bit line voltage difference such that the threshold voltage is not satisfied during the charge-transfer period.

The surprising result is that the charge-transfer depends upon the binary state stored by the bitcell. If this binary state equals the first binary value, the charge-transfer transistor conducts to change the sense node voltage from its default value. But if the binary state equals the second binary value, the charge-transfer transistor does not conduct charge so that the sense node voltage stays at its default value. Note that the capacitance of the sense node is relatively small compared to the bit line capacitance. The conduction of charge by the charge-transfer transistor will thus quickly change its state from the default state to substantially equal the bitcell-effected voltage. The resulting charge-transfer by the charge-transfer thus functions to amplify the bit line difference voltage in substantially a full rail fashion. In a conventional SRAM, the sense amplifier must be relatively sensitive to respond to the bit line voltage difference. In sharp contrast, a simple inverter may be used herein to sense the sense node voltage since it will widely swing from its default voltage due to the amplification provided by the charge-transfer function.

Note that the previous discussion is generic as to the polarity of the charge-transfer transistor. It may be either a p-type metal-oxide semiconductor (PMOS) transistor or an n-type metal-oxide semiconductor (NMOS) transistor. In both cases, the source is tied to the bit line whereas the drain is tied to the sense node. But the polarities are reversed. In a PMOS implementation, the bit-line is pre-charged to the power supply voltage VDD whereas the default voltage for the sense node is ground. But in an NMOS implementation, the bit line is pre-charged by being grounded whereas the default voltage for the sense node would equal the power supply voltage. The following discussion will focus on a PMOS implementation followed by discussion of an NMOS implementation.

In a PMOS charge-transfer embodiment, the bit line is pre-charged to the power supply voltage VDD before the word line is fired. The sense node is discharged to ground to its default state while the sense node is isolated from the pre-charged bit line through the PMOS charge-transfer transistor. With the word line asserted, the bitcell can then drive the precharged bit line to equal the bitcell-effected voltage. The bitcell-effected voltage equals the power supply voltage VDD if the binary content stored in the bitcell equals a first binary value. But the bitcell-effected voltage is reduced from the power supply voltage by the bit line voltage difference if the binary content equals a second binary value. The following discussion will assume that the first binary value is a binary one (logical one) value and that the second binary value is a binary zero (logical zero) value but these values may be reversed in alternative implementations.

As discussed earlier, the bit line voltage difference may be a relatively small value such as 100 millivolts or even less. This slight difference is quite significant, however, due to the charge-transfer amplification that is implemented by the PMOS charge-transfer transistor. With the bitcell-effected voltage developed on the bit line due to the word line being asserted, the PMOS charge-transfer transistor is not simply turned fully on as would be performed in a conventional memory but instead the gate voltage of the PMOS charge-transfer transistor charges so that the difference between the power supply voltage and the gate voltage is equal to or slightly below an absolute value of the threshold voltage for the PMOS charge-transfer transistor. Should the bitcell be storing a binary one value, the bitcell-effected voltage equals the power supply voltage VDD. The source-to-gate voltage for the PMOS charge-transfer transistor is thus slightly greater than the absolute value of the threshold voltage so that the PMOS charge-transfer transistor will switch on to transfer charge from the bit line to the discharged sense node. But if the bitcell is storing a binary zero value, the source-to-gate voltage for the PMOS charge-transfer transistor will be slightly below the power supply voltage due to the reduced value for the bitcell voltage. The PMOS charge-transfer transistor thus continues to isolate the discharged sense node when the bitcell is storing a binary zero due to the threshold voltage not being satisfied.

The resulting charge-transfer amplification due to the difference between the bit line capacitance and the sense node capacitance is quite advantageous because the sense amplifier may simply be an inverter. Such an inverter sense amplifier would then sense the binary content of the bitcell by inverting the sense node voltage. The inverter output will thus equal the power supply voltage if the binary content of the bitcell is a binary zero. Conversely, the inverter output would equal ground if the binary content of the bitcell is a binary one. In sharp contrast, a conventional memory cannot use an inverter as a sense amplifier because a conventional sense amplifier must make a bit decision based upon the relatively small bit line voltage difference.

An NMOS implementation is the complement of a PMOS embodiment such that the bit line would be discharged rather than pre-charged prior to the read operation. The sense node would be charged to a power supply voltage instead of discharged prior to the read operation. The gate voltage for the NMOS charge-transfer transistor is then charged to substantially equal the threshold voltage for NMOS charge-transfer transistor at the start of the charge-transfer period. Should the accessed bitcell be storing a binary zero value, the NMOS charge-transfer transistor will conduct charge so that the precharged sense node is discharged towards ground. But if the accessed bitcell is storing a binary one, the accessed bitcell will raise the voltage of discharged bit line by the bit line voltage difference such that the NMOS charge-transfer transistor does not conduct since its gate-to-source voltage is then below its threshold voltage. Some example PMOS charge-transfer embodiments will now be discussed in more detail followed by a discussion of an NMOS charge-transfer embodiment.

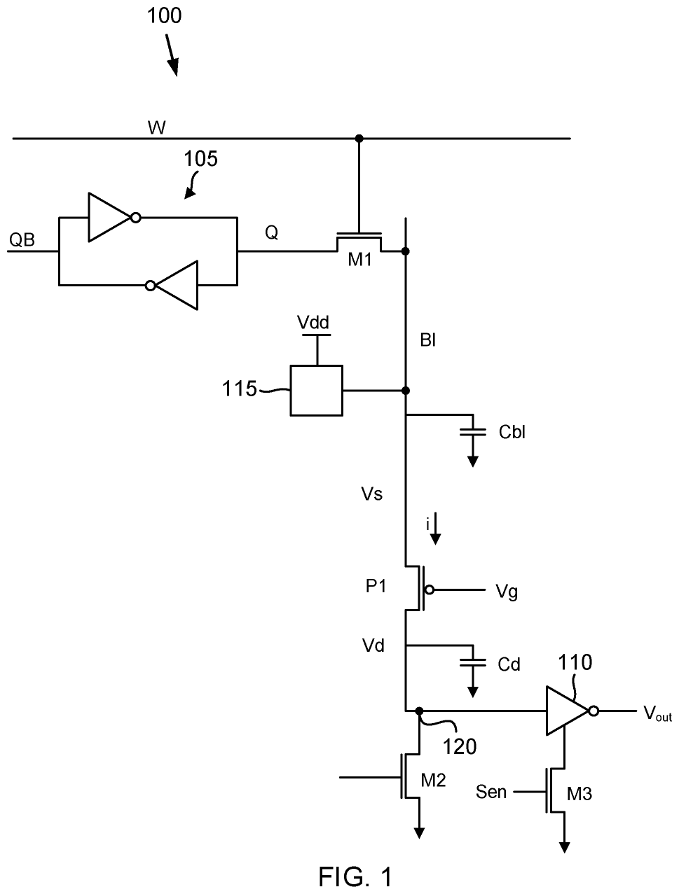

An example SRAM 100 is shown in FIG. 1. As known in the SRAM arts, SRAM 100 includes a plurality of bitcells 105 arranged in rows according to a plurality of word lines and arranged in columns according to a plurality of bit lines. For illustration clarity, only one word line W, one bitcell 105, and one bit line Bl is shown in FIG. 1. Prior to the read operation, a Q node for bitcell 105 is charged to a power supply voltage if bitcell 105 is storing a binary one value. Conversely, the Q node is grounded if bitcell 105 is storing a binary zero. As known in the SRAM arts, a pre-charge circuit 115 functions to pre-charge bit line Bl to a power supply voltage VDD prior to the assertion of word line W. During the read operation, a voltage for the word line W is asserted to the power supply voltage to switch on an NMOS access transistor M1 so that the Q node is coupled to the pre-charged bit line Bl. The bit line voltage will then be charged to the bitcell-effected voltage that depends upon the Q node voltage. The bitcell-effected voltage will equal the power supply voltage VDD if bitcell 105 is storing a binary one but will be reduced from the power supply voltage VDD by the bit line voltage difference if bitcell 105 is storing a binary zero. Note that the capacitance of the bit line Bl is relatively large as represented by a bit cell capacitance Cbl. Bitcell 105 thus cannot discharge bit line Bl to zero during the relatively brief period that the word line W is asserted should bitcell 105 be storing a binary zero. Instead, the bit line voltage is reduced from the power supply voltage by the bit line voltage difference that equals some fraction of the power supply voltage VDD (e.g., 100 mV).

The bitcell-effected voltage for the bit line Bl thus equals the power supply voltage minus the bit line voltage difference (dvbl) when bitcell 105 is storing a binary zero value during the read operation. It is this bit line voltage difference that prevents a charge transfer from occurring across a PMOS charge-transfer transistor P1 that isolates a sense node 120 from the bit line Bl prior to the read operation. A charge-transfer driver (not illustrated but discussed further below) charges a gate voltage Vg for charge-transfer transistor P1 to the power supply voltage prior to the read operation so that charge-transfer transistor P1 isolates sense node 120 from the bit line Bl. The sense node voltage equals a drain voltage Vd for charge-transfer transistor P1 whereas the bit line voltage equals a source voltage Vs for charge-transfer transistor P1. Prior to the read operation, a discharge circuit such as an NMOS transistor M2 that couples between ground and sense node 120 is switched on to discharge sense node voltage Vd. A capacitance Cd of sense node 120 is relatively small compared to the bit line capacitance Cbl. This small capacitance Cd for sense node 120 effectively causes a charge-transfer amplification as will be discussed further herein.

A sense amplifier inverter 110 inverts the sense node voltage during a sense-enable period following the charge-transfer period for the read operation. For example, a sense-enable signal Sen may be asserted to switch on an NMOS transistor M3 that couples between ground and a ground node for inverter 110 to switch on inverter 110 during the sense-enable period. An output voltage Vout for inverter 110 will be asserted to the power supply voltage if the sense node voltage Vd is still discharged during the sense-enable period. Conversely, the output voltage Vout will be discharged to ground if the sense-enable voltage is charged above a threshold for inverter 110 during the sense-enable period.

To control the charge-transfer through charge-transfer transistor P1, the charge-transfer driver charges the gate voltage to a voltage Vg during the charge-transfer period. The voltage Vg equals the power supply voltage VDD minus a sum of the absolute value of the threshold voltage for transistor P1 and an additional positive overdrive voltage Vx so that the voltage Vg equals VDD−(Abs(Vt)+Vx), where Abs represents the absolute value function. A resulting source-to-gate voltage Vsg for charge-transfer transistor P1 then depends the bitcell-effected voltage for bit line Bl since the bitcell-effected voltage is also the source voltage for charge-transfer transistor P1. In turn, the bitcell-effected voltage for the bit line Bl depends upon the binary value for bitcell 105.

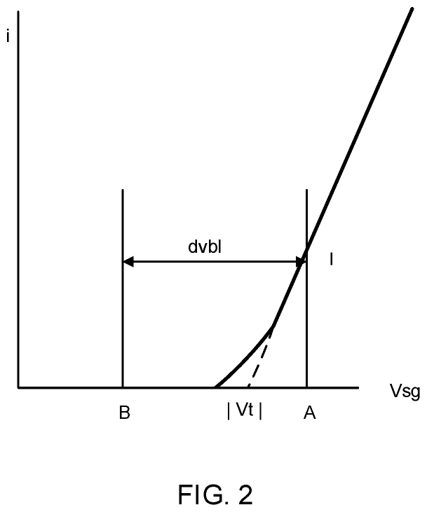

The resulting charge-transfer control by charge-transfer transistor P1 may be better appreciated through a consideration of FIG. 2, which illustrates the current i conducted by charge-transfer transistor P1 as a function of its source-to-gate voltage Vsg. Should the bitcell-effected voltage equal the power supply voltage VDD, the source-to-drain voltage Vsg will equal VDD−Vg, which equals VDD−(VDD−(Abs(Vt)+Vx)), which in turn equals Abs(Vt)+Vx as represented by voltage A in FIG. 2. Since voltage A is greater than the absolute value of the threshold voltage, charge-transfer transistor P1 is switched on to conduct a current I. But if bitcell 105 is storing a binary zero, the source voltage for charge-transfer transistor P1 (the bitcell-effected voltage) is reduced from the power supply voltage VDD by the bit line voltage difference (dvbl). The voltage Vsg then equals Abs(Vt)+Vx−dvbl, which equals a voltage B as shown in FIG. 2. Since voltage B is less than the absolute value of the threshold voltage, charge-transfer transistor P1 remains off and conducts a negligible amount of charge.

The sense node voltage Vd will thus remain discharged if bitcell 105 is storing a binary zero whereas charge-transfer transistor P1 will conduct current I if bitcell 105 is storing a binary one. Since the capacitance Cd of the sense node is relatively small, the current I will relatively quickly charge the sense node voltage Vd from ground towards the bitcell-effected voltage. The bit line voltage difference dvbl is thus amplified to by the charge-transfer process to result in a sense node voltage difference that is nearly full rail. This amplification advantageously enables the use of inverter 110 to sense the sense node voltage. Not only is inverter 110 relatively compact and low-power as compared to a conventional sense amplifier but memory 100 may use just one bit line per bitcell as compared to the conventional need for an SRAM bit line pair. The sensing of the bitcell binary content by inverter 110 may thus be denoted as a single-ended sensing since it uses just one bit line.

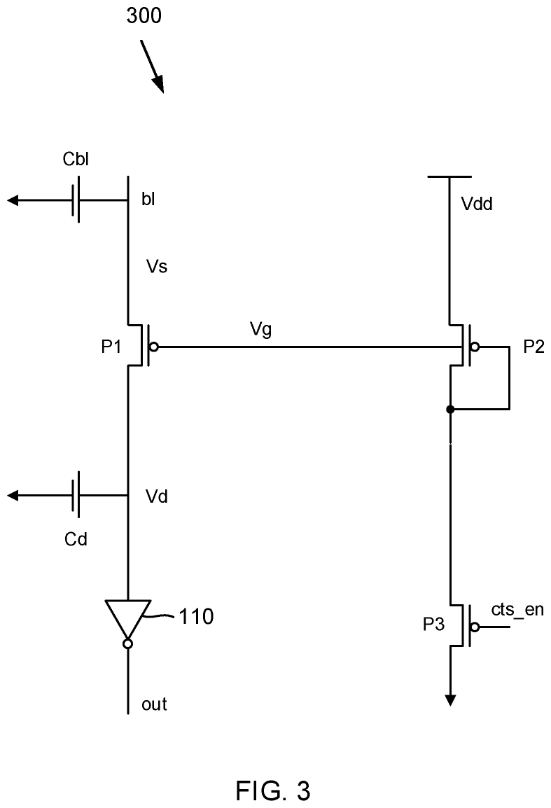

The charge-transfer driver for the generation of the gate voltage Vg may be formed using a diode-connected PMOS transistor P2 as shown in FIG. 3 for an SRAM 300. A source for diode-connected transistor P2 is tied to a power supply node for the power supply voltage VDD whereas its gate and drain are tied to a source for a PMOS current-source transistor P3 that is switched on during the charge-transfer period by an active-low charge-transfer enable signal (cts_en). Transistor P3 will then conduct a current Is during the charge-transfer period. Diode-connected transistor P2 has its gate connected to the gate of charge-transfer transistor P1. Charge-transfer transistor P1 will thus mirror the current Is during the charge-transfer period depending upon the size ratios between transistors P1 and P2 should the source of charge-transfer transistor P1 also be charged to the power supply voltage VDD. As discussed previously, the bitcell-effected voltage for the bit line Bl equals the power supply voltage VDD when bitcell 105 (FIG. 1) is storing a binary one value. Charge-transfer transistor P1 thus switches on to pass current Is during the charge-transfer period when the bitcell-effected voltage equals the power supply voltage VDD. But if the bitcell-effected voltage is dropped from the power supply voltage VDD by the bit line voltage difference bit line dvbl due to a binary zero value stored in bitcell 105, the current mirror configuration is broken such that charge-transfer transistor P1 conducts a negligible amount of charge. Note that a diode-connected transistor such as transistor P2 will conduct an appreciable amount of charge to ground such that efficiency is reduced.

An alternative charge-transfer driver that does not have the efficiency costs of using a diode-connected transistor may be developed by any suitable source that drops the gate voltage relatively slowly as compared to the development of the bit line voltage difference dvbl. The goal is that the gate voltage Vg be reduced at the beginning of the charge-transfer period from the power supply voltage by approximately the absolute value of the threshold voltage. Should the source voltage (the bitcell-effected voltage) for charge-transfer transistor P1 then equal the power supply voltage VDD, the Vsg voltage for charge-transfer transistor P1 will equal the absolute value of the threshold voltage so that charge-transfer transistor P1 will conduct. But if the source voltage equals the power supply voltage minus the bit line voltage difference dvbl, charge-transfer transistor P1 will not conduct.

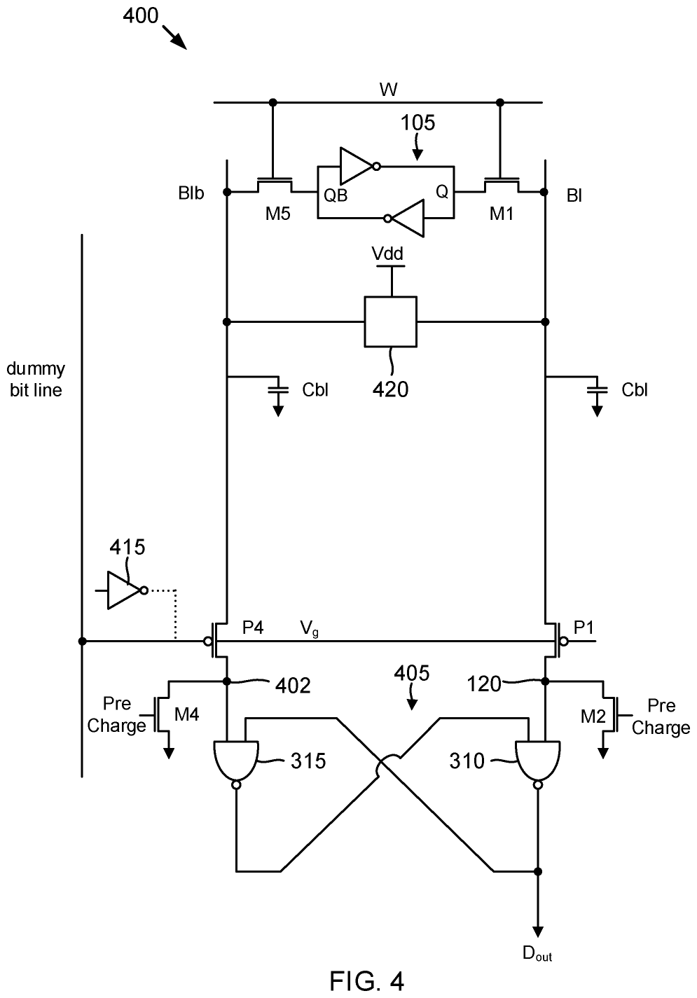

One way to relatively slowly drop the gate voltage Vg is to form the charge-transfer driver using a small inverter. Due to its relatively small size, the inverter would drop the gate voltage relatively slowly during the charge-transfer period. As an alternative, a dummy bit line may be used to function as the charge-transfer driver to form the gate voltage Vg. As known in the SRAM arts, a dummy bit line is used to model when the bit line voltage has developed sufficiently so that the sense-enable period should be started. Since the dummy bit line models the capacitance of the bit line, the dummy bit line discharges from a pre-charged state to a threshold voltage at approximately the same rate that the bit line discharges from the power supply voltage to the bit line voltage difference dvbl. Both types of charge-transfer drivers are shown in FIG. 4 for a memory 400. Since only one method would be used in practice, the connection from an inverter 415 to the gate voltage for charge-transfer transistor P1 is shown by an optional dotted line. In addition, memory 400 uses a bit line pair formed by a bit line Bl and a complement bit line Blb as opposed to the single-ended approach discussed for memory 100. Although a bit line pair requires more routing, the resulting sense operation may be performed more quickly as opposed to the single-ended approach. Memory 100 may thus be utilized for less time-critical applications whereas memory 400 offers faster operation for more time-critical applications.

Prior to the assertion of word line W, a pre-charge circuit 420 functions to pre-charge bit line Bl and complement bit line Blb as known in the SRAM arts. A Q node for bitcell 105 couples through access transistor M1 to bit line Bl as discussed for memory 100. In addition, a complement Q node (QB) for bitcell 105 in memory 400 couples through another NMOS access transistor M5 to complement bit line Blb. Bit line Bl is isolated from sense node 120 by charge-transfer transistor P1 as discussed with regard to memory 100. Similarly, complement bit line Blb is isolated from a sense node 402 by a PMOS charge-transfer transistor P4. The charge-transfer driver (the dummy bit line or inverter 415) controls the gate voltage for charge-transfer transistors P1 and P4 during the charge-transfer period. Transistor M2 and a transistor M4 function as a discharge circuit to discharge sense nodes 120 and 402 prior to the charge-transfer period. Transistor M4 has a source connected to ground and a drain connected to sense node 402. Transistor M2 is arranged as discussed for SRAM 100.

A sense amplifier in memory 400 is formed by a simple reset-set (RS) latch such as implemented through a pair of cross-coupled NAND gates 315 and 310. NAND gate 310 has a first input node connected to sense node 120 and a second input node connected to an output node for NAND gate 315. Similarly, NAND gate 315 has a first input node connected to sense node 402 and a second input node connected to an output node for NAND gate 310. The output node for NAND gate 310 drives an output signal Dout for the read operation on bitcell 105. The RS latch formed by NAND gates 310 and 315 is relatively compact and efficient as compared to a conventional sense amplifier. Due to the discharged default state for sense nodes 120 and 402, the outputs for NAND gates 315 and 310 will both be logic high (charged to the power supply voltage) prior to the charge-transfer period. Each NAND gate then acts as an inverter to its sense node (the drain of charge-transfer transistor P4 or of charge-transfer transistor P1). Should bitcell 105 be storing a binary one value, charge-transfer transistor P1 will conduct during the charge-transfer period whereas charge-transfer transistor P4 will remain off. In such a state, the RS latch formed by NAND gates 310 and 315 resets such that the output signal Dout is discharged to ground. Conversely, if bitcell 105 is storing a binary zero value, charge-transfer transistor P4 will conduct during the charge-transfer period whereas charge-transfer transistor P1 will remain off. The RS latch formed by NAND gates 310 and 315 will then set such that the output signal Dout charges to the power supply voltage VDD. Note that the RS latch may advantageously read without failure even if there is an unwanted charge-transfer due to leakage for the bit lines when the accessed bitcell is storing a binary zero value.

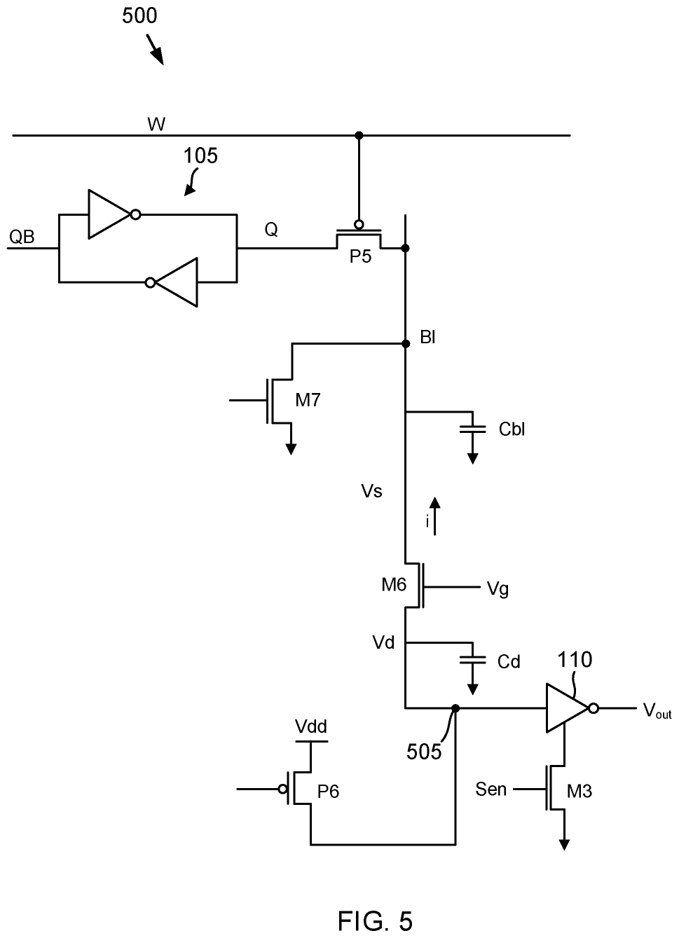

An NMOS charge-transfer embodiment will now be discussed with reference to an example SRAM 500 shown in FIG. 5. A bit line Bl couples to a bitcell 105 during a read operation analogously as discussed with regard to memory 100. During a charge-transfer period, the bit line Bl couples through an NMOS charge-transfer transistor M6 to a sense node 505 (the drain of charge-transfer transistor M6). As discussed with regard to memory 100, a sense amplifier inverter 110 in memory 500 senses a bit stored in bitcell 105 by inverting the sense node voltage (the drain voltage Vd for charge-transfer transistor M6). The pre-charge state for the bit line Bl is ground as discharged by a pre-charge NMOS transistor M7. Conversely, the pre-charge state for sense node 505 is the power supply voltage VDD as charged through a charge circuit such as a pre-charge PMOS transistor P6.

Since the pre-charge state for the bit line Bl is ground, the access transistor is a PMOS transistor as represented by an access transistor P5. The assertion of the word line W for memory 500 may then be an active-low (ground) assertion. Prior to the read operation, the default state for the word line is the power supply voltage VDD to keep access transistor P5 off. But during the read operation, the word line W is then discharged to ground for a word line period. Depending upon the bit stored in bitcell 105, the bit line Bl will then either remain grounded (staying at its pre-charged state) due to the stored bit being a binary zero or will be boosted in voltage by a fraction of the power supply voltage VDD due to the stored bit being a binary one.

Prior to the charge-transfer period, the gate of charge-transfer transistor M6 is grounded so that transistor M6 is off. During the charge-transfer period, the gate voltage for charge-transfer transistor M6 is slowly boosted to its threshold voltage plus a positive overdrive voltage (some fraction of the power supply voltage VDD). A small inverter is thus suitable to function as a charge-transfer driver to charge the gate voltage for charge-transfer transistor M6. This gate drive is analogous to inverter 415 discussed with regard to memory 400 except that the gate voltage will charge from ground during the charge-transfer period for memory 500 whereas it discharges from the power supply voltage VDD for memory 400. With the gate voltage Vg charged to the threshold voltage and bitcell 105 storing a binary zero, the gate-to-source voltage for charge-transfer transistor M6 will satisfy its threshold voltage so that charge from the pre-charged sense node 505 flows onto the bit line Bl. But the bit line voltage is not significantly boosted by this charge-transfer due to the relatively larger bit line capacitance Cbl as compared to the smaller sense node capacitance Cd. In contrast, the voltage of the pre-charged sense node 505 will change more significantly and be discharged towards ground so as to trigger inverter 110 to charge the output voltage Vout to the power supply voltage VDD.

Should the stored bit in bitcell 105 instead be a binary one, bitcell 105 will boost the discharged bit line voltage by the bit line voltage difference dvbl. Since the gate voltage of charge-transfer transistor M6 is just slightly above its threshold voltage, the boosting of the source voltage for charge-transfer transistor M6 by the bit line voltage difference dvbl keeps charge-transfer transistor M6 off during the charge-transfer period. The pre-charged sense node voltage will then stay at the power supply voltage VDD so that inverter 110 keeps the output voltage Vout discharged. In this fashion, the charge-transfer operation may be implemented regardless of the polarity of the charge-transfer transistor. Note, however, that operation of SRAM 500 is quite foreign to conventional SRAM operation in that the pre-charged state of bit line Bl is ground and access transistor P6 is a PMOS transistor. Although such operation is very different from conventional SRAM operation, the pre-charging of the bit line is low power since the pre-charge state is ground. SRAM 500 is single-ended, but it will be appreciated that such an NMOS charge-transfer operation is readily extended to a double-ended implementation such as discussed analogously with regard to memory 400. However, note that the cross-coupled NAND gates would be replaced by cross-coupled NOR gates to form the sense amplifier in an NMOS charge-transfer embodiment.

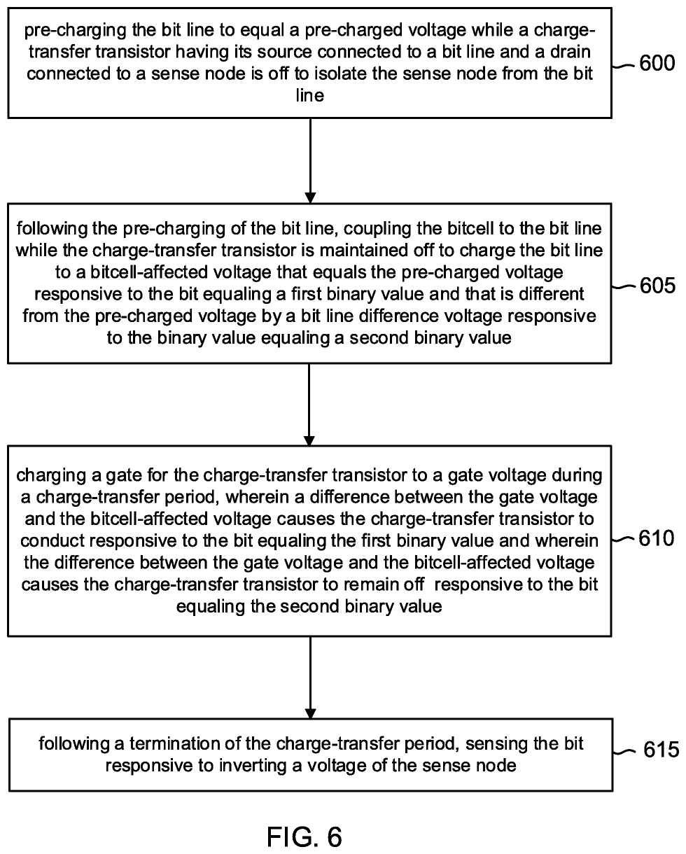

A charge-transfer method of sensing the bit stored by a bitcell will now be discussed with regard to the flowchart shown in FIG. 6. The method includes an act 600 of pre-charging the bit line to equal a pre-charged voltage while a charge-transfer transistor having its source connected to a bit line and a drain connected to a sense node is off to isolate the sense node from the bit line. An example of act 600 is the pre-charging of bit line Bl in memory 100 or 400 while charge-transfer transistor P1 is off. In addition, the method includes an act 605 that follows the pre-charging of the bit line and includes coupling the bitcell to the bit line while the charge-transfer transistor is maintained off to charge the bit line to a bitcell-effected voltage that equals the pre-charged voltage responsive to the bit equaling a first binary value and that is different from the pre-charged voltage by a bit line difference voltage responsive to the bit equaling a second binary value. Note that act 605 is generic to the polarity of the charge-transfer transistor. In an NMOS implementation such as discussed for SRAM 500, the pre-charged voltage equals ground whereas it equals the power supply voltage in an PMOS implementation.

The method further includes an act 610 of charging a gate for the charge-transfer transistor to a gate voltage during a charge-transfer period, wherein a difference between the gate voltage and the bitcell-effected voltage causes the charge-transfer transistor to conduct responsive to the bit equaling the first binary value and wherein the difference between the gate voltage and the bitcell-effected voltage causes the charge-transfer transistor to remain off responsive to the bit equaling the second binary value. Like act 605, act 610 is generic to the polarity of the charge-transfer transistor.

Finally, the method includes an act 615 that follows a termination of the charge-transfer period and includes sensing the bit responsive to inverting a voltage of the sense node. This inversion may be performed by inverter 110 in a single-ended implementation or by NAND gate 310 in a double-ended implementation.

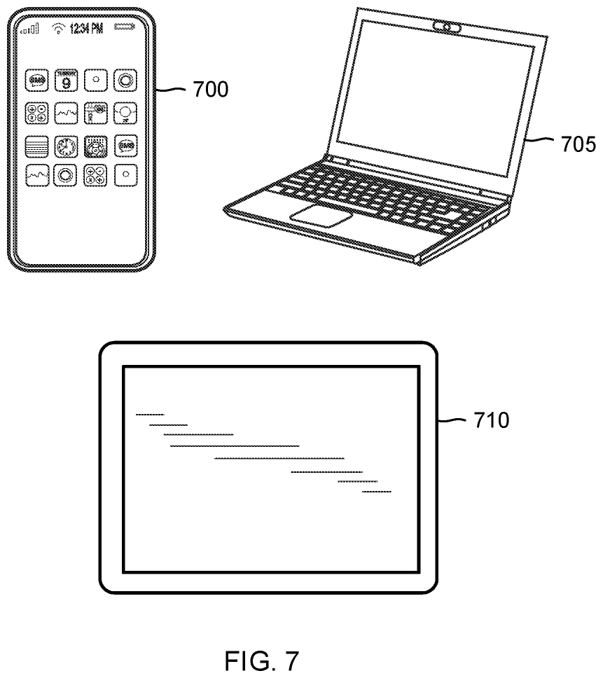

The memories disclosed herein may be advantageously incorporated into any suitable electronic system or device. For example, as shown in FIG. 7, a cellular telephone 700, a laptop computer 705, and a tablet PC 710 may all include a memory in accordance with the disclosure. Other exemplary electronic systems such as a music player, a video player, a communication device, and a personal computer may also be configured with memories constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A memory, comprising:
a bit line;
a bitcell configured to charge the bit line to a bitcell-effected voltage during a word line assertion period responsive to a stored bit in the bitcell;
a sense amplifier;
a first sense node for the sense amplifier;
a first charge-transfer transistor having a source connected to the bit line and a drain connected to the first sense node; and
a charge-transfer driver configured to charge a gate of the first charge-transfer transistor to a gate voltage during a charge-transfer period to cause the first charge-transfer transistor to conduct responsive to the stored bit being equal to a first binary value and to cause the first charge-transfer transistor to remain off responsive to the stored bit being equal to a complement of the first binary value.

2. The memory of claim 1, further comprising:
a pre-charge circuit configured to charge the bit line to a power supply voltage during a pre-charge period, and wherein the first charge-transfer transistor is a p-type metal-oxide-semiconductor (PMOS) transistor.

3. The memory of claim 2, further comprising a transistor configured to discharge the first sense node to ground during the pre-charge period.

4. The memory of claim 1, further comprising:
a pre-charge circuit configured to discharge the bit line to ground during a pre-charge period, and wherein the first charge-transfer transistor is an n-type metal-oxide-semiconductor (NMOS) transistor.

5. The memory of claim 4, further comprising a transistor configured to charge the first sense node to a power supply voltage during the pre-charge period.

6. The memory of claim 1, wherein the charge-transfer driver comprises a dummy bit line.

7. The memory of claim 1, wherein the charge-transfer driver comprises an inverter.

8. The memory of claim 1, wherein the charge-transfer driver comprises a diode-connected transistor having a gate connected to a gate of the first charge-transfer transistor.

9. The memory of claim 1, wherein the sense amplifier comprises an inverter configured to invert a voltage of the first sense node to sense a binary value of the stored bit.

10. The memory of claim 1, further comprising:
a complement bit line;
a second charge-transfer transistor having a source connected to the complement bit line and a drain connected to a second sense node for the sense amplifier, wherein the charge-transfer driver is further configured to drive a gate voltage for the second charge-transfer transistor.

11. The memory of claim 10, wherein the sense amplifier comprises a reset-set latch.

12. The memory of claim 11, wherein the reset-set latch comprises a pair of cross-coupled NAND gates.

13. The memory of claim 1, wherein the memory is incorporated into a cellular telephone.

14. A method for sensing a bit stored by a bitcell using a charge-transfer transistor, comprising:
pre-charging a bit line to equal a pre-charged voltage while a charge-transfer transistor having a source connected to the bit line and a drain connected to a sense node is off to isolate the sense node from the bit line;
following the pre-charging of the bit line, coupling the bitcell to the bit line while the charge-transfer transistor is maintained off to charge the bit line to a bitcell-effected voltage that equals the pre-charged voltage responsive to the bit equaling a first binary value and that is different from the pre-charged voltage by a bit line difference voltage responsive to the bit equaling a second binary value;
charging a gate of the charge-transfer transistor to a gate voltage during a charge-transfer period, wherein a difference between the gate voltage and the bitcell-effected voltage causes the charge-transfer transistor to conduct responsive to the bit equaling the first binary value and wherein the difference between the gate voltage and the bitcell-effected voltage causes the charge-transfer transistor to remain off responsive to the bit equaling the second binary value; and
following a termination of the charge-transfer period, sensing the bit responsive to inverting a voltage of the sense node.

15. The method of claim 14, wherein the pre-charging the bit line to equal the pre-charged voltage comprises charging the bit line to a power supply voltage for a pre-charge period.

16. The method of claim 15, further comprising discharging the sense node to ground prior to the charge-transfer period.

17. The method of claim 14, wherein the first binary value is a logical one and the second binary value is a logical zero.

18. The method of claim 15, wherein the charging the gate of the charge-transfer transistor to the gate voltage comprises charging the gate of the charge-transfer transistor using a dummy bit line.

19. The method of claim 15, wherein the charging the gate of the charge-transfer transistor to the gate voltage comprises discharging the gate of the charge-transfer transistor using an inverter.

20. A memory, comprising:
a bit line;
a bitcell configured to charge the bit line to a bitcell-effected voltage during a read operation responsive to a bit stored by the bitcell;
a sense amplifier inverter;
a charge-transfer transistor coupled between the bit line and a sense node for the sense amplifier inverter; and
a discharge circuit configured to discharge the sense node to ground prior to a charge-transfer period for the charge-transfer transistor.

21. The memory of claim 20, further comprising:
a pre-charge circuit configured to pre-charge the bit line to a pre-charge voltage prior to the charge-transfer period.

22. The memory of claim 20, further comprising:
a charge-transfer driver configured to drive a gate voltage of the charge-transfer transistor during the charge-transfer period.

23. The memory of claim 22, wherein the charge-transfer driver comprises a dummy bit line.

24. The memory of claim 22, wherein the charge-transfer driver comprises an inverter configured to discharge the gate voltage of the charge-transfer transistor during the charge-transfer period.

25. A memory, comprising:
a bit line;
a bitcell configured to charge the bit line to a bitcell-effected voltage during a read operation responsive to a bit stored by the bitcell;
a sense amplifier inverter;
a charge-transfer transistor coupled between the bit line and a sense node for the sense amplifier inverter; and
a charge circuit configured to charge the sense node to a power supply voltage prior to a charge-transfer period for the charge-transfer transistor.

26. The memory of claim 25, further comprising:
a pre-charge circuit configured to discharge the bit line to ground prior to the charge-transfer period.

27. The memory of claim 25, further comprising:
a charge-transfer driver configured to drive a gate voltage of the charge-transfer transistor during the charge-transfer period.

28. The memory of claim 27, wherein the charge-transfer driver comprises a dummy bit line.

29. The memory of claim 27, wherein the charge-transfer driver comprises an inverter configured to charge the gate voltage of the charge-transfer transistor during the charge-transfer period.
